(19) United States
(12) Patent Application Publication
(10) Pub. No.: US 2016/0299843 A1
(43) Pub. Date: Oct. 13, 2016

(54) UNIFIED NON-VOLATILE MEMORY AND ELECTRONIC APPARATUS APPLYING THE NON-VOLATILE MEMORY

(71) Applicant: Nanya Technology Corp., Taoyuan City (TW)

(72) Inventors: Da-Zen Chuang, Taipei City (TW); Chi-Hsiang Kuo, Taoyuan City (TW)

(21) Appl. No.: 14/682,078

(22) Filed: Apr. 8, 2015

(51) Int. Cl. G06F 12/06; G11C 7/10; G11C 14/00; G06F 12/02

(52) U.S. Cl. CPC G06F 12/0638; G06F 12/0238; G11C 7/1072; G11C 14/009; G11C 14/0081; G06F 2212/205; G06F 2212/202; G11C 13/0002

(57) ABSTRACT

Discloses is a unified non-volatile memory comprising: a first memory section, served as a read only memory; and a second memory section, served as a random access memory. An electronic apparatus applying the unified non-volatile memory is also disclosed.

### BACKGROUND OF THE INVENTION

1. Field of the Invention

The present invention relates to a unified non-volatile memory and an electronic apparatus applying the unified non-volatile memory, and particularly relates to a unified non-volatile memory comprises sections served as different type of memories and an electronic apparatus applying the unified non-volatile memory.

2. Description of the Prior Art

A conventional electronic apparatus always comprises at least one volatile memory and a non-volatile memory for different applications. Many applications have disclosed such architecture. For example, the US application with a publication number US 20110623, the US application with a publication number US 20121023, and the US application with a publication number US 20140130.

FIG. 1 is a block diagram illustrating a conventional electronic apparatus. As show in FIG. 1, the electronic apparatus 100 comprises a volatile memory 101, a non-volatile memory 103, and a control unit 105. The volatile memory 101, for example, a DRAM (Dynamic Random Access Memory) or a SRAM (Static Random Access Memory), can keep data when it is provided power but loses data while power is removed. On the contrary, the non-volatile memory 103, for example, a ROM (read only memory) or a flash memory, can keep data even it is not provided power.

Since the non-volatile memory 103 has lower cost, the non-volatile memory 103 is applied as a main storage to store data necessary for the electronic apparatus, for example, the code for the control unit 105. However, the access speed of the non-volatile memory 103 is low. Therefore, the volatile memory 101 is always applied to temporarily store data to speed up the access operation for the whole electronic apparatus 100, since the volatile memory 101 has high access speed.

However, the volatile memory 101 has high cost. Also, some volatile memories such as DRAMs need to be frequently refreshed thus the power consumption is high, such that the battery life for the electronic apparatus is short.

Therefore, an electronic apparatus which needs long battery life is not suitable to apply the architecture depicted in FIG. 1.

### SUMMARY OF THE INVENTION

Therefore, one objective of the present invention is to provide a unified non-volatile memory that comprises a polarity of memory sections served as different type of memories.

Another objective of the present invention is to provide an electronic apparatus comprising a unified non-volatile memory that comprises a polarity of memory sections served as different type of memories.

One embodiment of the present application discloses a unified non-volatile memory comprising: a first memory section, served as a read only memory; and a second memory section, served as a random access memory.

One embodiment of the present invention discloses an electronic apparatus, which comprises a unified non-volatile memory and a control unit. The unified non-volatile memory comprises: a first memory section, served as a read only memory; and a second memory section, served as a random access memory. The control unit controls the unified non-volatile memory.

In view of above-mentioned embodiments, a unified non-violate memory is applied to replace two independent memories (a non-violate memory and a volatile memory in FIG. 1), thus the chip size is reduced and simplified. Also, the power consumption is low since no volatile memory is needed. Further, the yield is better and overall manufacture cost is low since only a single manufacture process is needed. Besides, the data retention and the endurance for the memory raises since only non-volatile memories are used.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a conventional electronic apparatus comprising a volatile memory and a non-volatile memory.

FIG. 2 is a block diagram illustrating a unified non-volatile memory according to one embodiment of the present invention.

FIG. 3, FIG. 4 are examples for the unified non-volatile memory depicted in FIG. 2.

FIG. 5 is a block diagram illustrating an electronic apparatus applying the unified non-volatile memory depicted in FIG. 2.

FIG. 6 is a block diagram illustrating a unified non-volatile memory according to another embodiment of the present invention.

FIG. 7 is a block diagram illustrating an electronic apparatus applying the unified non-volatile memory depicted in FIG. 6.

FIG. 8A and FIG. 8B are block diagrams illustrating unified non-volatile memories according to other embodiments of the present invention.

FIG. 9 is a schematic diagram illustrating an electronic apparatus applying IOT according to one embodiment of the present application.

### DETAILED DESCRIPTION

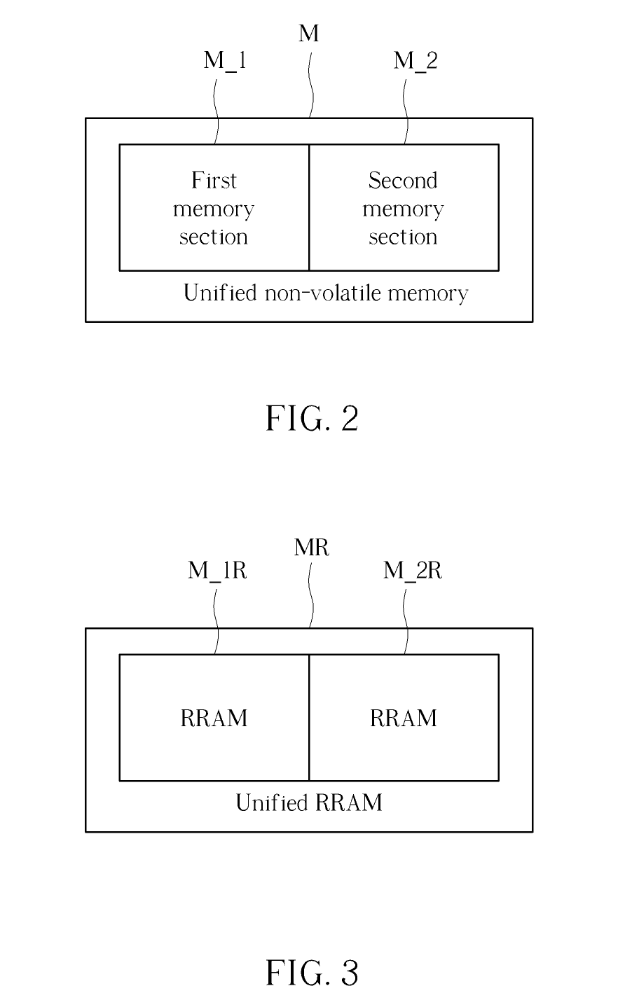

FIG. 2 is a block diagram illustrating a unified non-volatile memory according to one embodiment of the present invention. As illustrated in FIG. 2, the unified non-volatile memory M comprises a first memory section M_1 and a second memory section M_2, which serve as different types of memories. For more detail, the first memory section M_1 is served as a read only memory (ROM), and the second memory section M_2 is served as a random access memory (RAM).

Please note, the first memory section M_1 and the second memory section M_2 are built in a unified memory (i.e. the same memory), rather than two independent memories. Therefore, the first memory section M_1 and the second memory section M_2 are simultaneously manufactured by only one manufacturing process, rather than respectively manufactured by different manufacturing processes. Accordingly, the manufacturing for the unified non-volatile memory M is more simplified than the manufacturing for a plurality of memories.

The characteristics (ex. endurance, data retention) of the first memory section M_1 and the second memory section M_2 can be adjusted by varying manufacturing parameters. For example, vary doping density, or vary layer thickness, or vary sizes for all devices. By these ways, the characteristics of the first memory section M_1 and the second memory section M_2 can be adjusted to desired values. However, please note the methods for adjusting the characteristics of the first memory section M_1 and the second memory section M_2 are not limited to above-mentioned example.

In one embodiment, the memory endurance (i.e. the maximum access times) of the second memory section M_2 is higher than memory endurance of the first memory section M_1. For example, the first memory section M_1 has endurance of 10⁶ times for accessing, and the second memory section M_2 has endurance larger than 10¹²˜10¹⁵ times for accessing. Also, in one embodiment, the data retention (i.e. the time that the data can be kept) of the second memory section M_2 is lower than data retention of the first memory section M_1. For example, the first memory section M_1 has data retention larger than 10 years, and the second memory section M_2 has data retention for 1 sec or 1 min. However, it will be appreciated that other characteristics of the first memory section M_1 and the second memory section M_2 can be adjusted as well to meet different requirements.

The unified non-volatile memory M can be any type of non-volatile memory. For example, as shown in FIG. 3, the unified non-volatile memory is a unified RRAM (Resistive random-access memory) MR, thus the first memory section and the second memory section are RRAMs M_1R, M_2R as well. For another example, as shown in FIG. 4, the unified non-volatile memory is a unified PRAM (Parameter Random Access Memory) MP, thus the first memory section and the second memory section are PRAMs M_1P, M_2P as well. In other examples, a phase change random access memory (PCRAM), a magnetoresistive random access memory(MRAM), a ferroelectric random access memory (FRAM), a conductive-bridging random access memory (CBRAM), and a resistive random access memory (ReRAM) can all be applied as the unified non-volatile memory M.

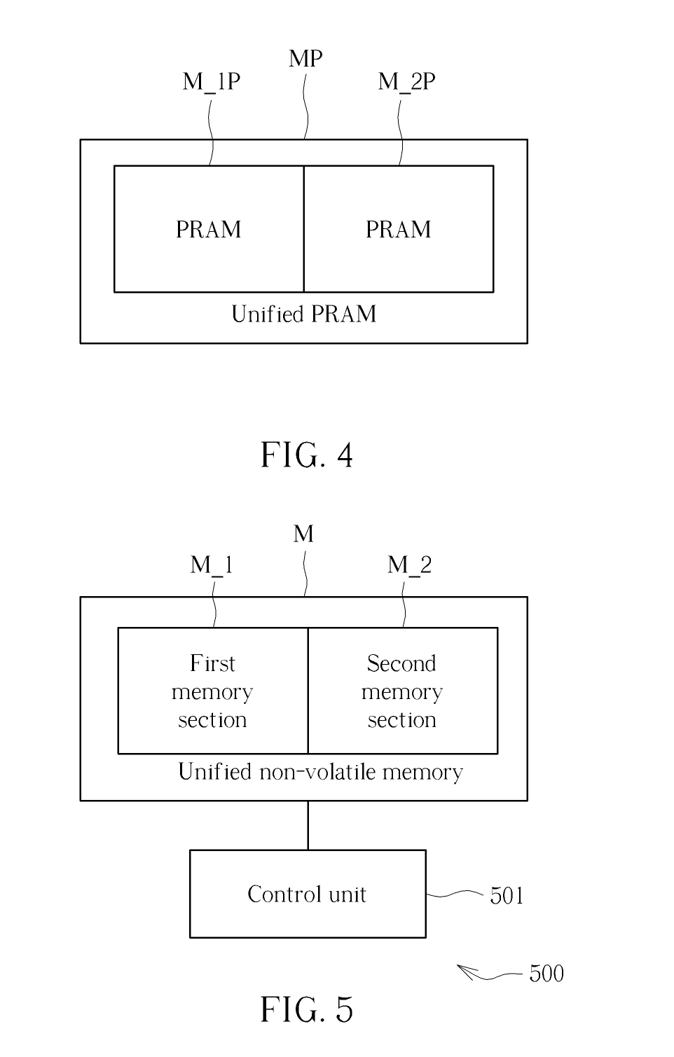

FIG. 5 is a block diagram illustrating an electronic apparatus applying the unified non-volatile memory depicted in FIG. 2. As shown in FIG. 5, the electronic apparatus 500 comprises a control unit 501 and the unified non-volatile memory M depicted in FIG. 2. The control unit 501 controls the unified non-volatile memory M. That is, the control unit 501 can access the unified non-volatile memory M. In one embodiment, the control unit 501 controls the operations for the electronic apparatus in which the unified non-volatile memory M is provided, but not limited. In such embodiment, the first memory section M_1 stores the code necessary for the control unit 501 since it is served as a ROM. That is, the first memory section M_1 is served as a code memory for the control unit 501. Please note the control unit in the embodiment of FIG. 5 can be named for other terms in other applications, for example, a micro unit, a micro-processor, or a processor. Also, it will be appreciated that the electronic apparatus 500 can further comprise other devices, such as a real time clock, but not limited here. Further, please note the unified non-volatile memory can comprise more than two memory sections, e.g. the second memory section M_2 which is served as a RAM.

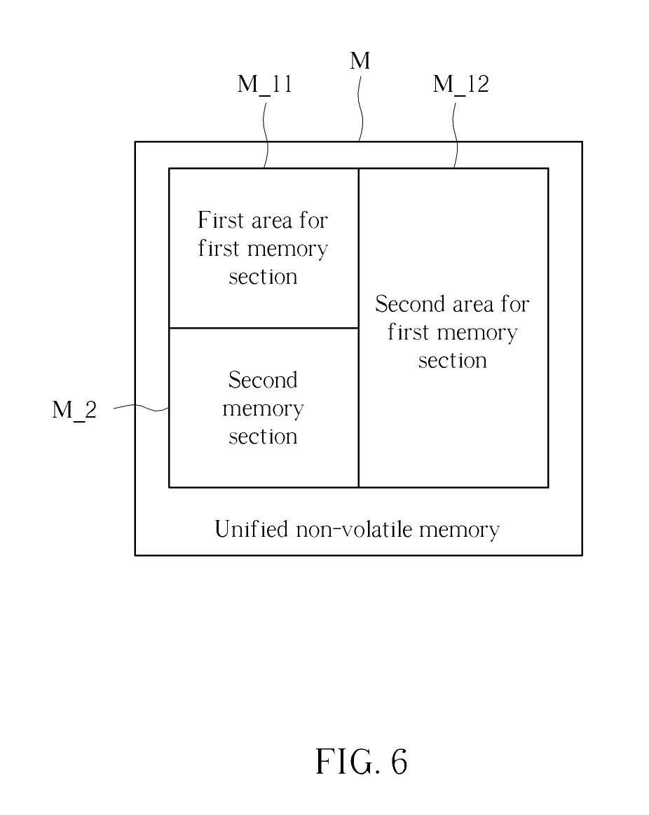

FIG. 6 is a block diagram illustrating a unified non-volatile memory according to another embodiment of the present invention. In such embodiment, the first memory section further comprises a first area for first memory section M_11 and a second area for first memory section M_12. The first area for first memory section M_11 and a second area for first memory section M_12 provide different functions, which will be described later.

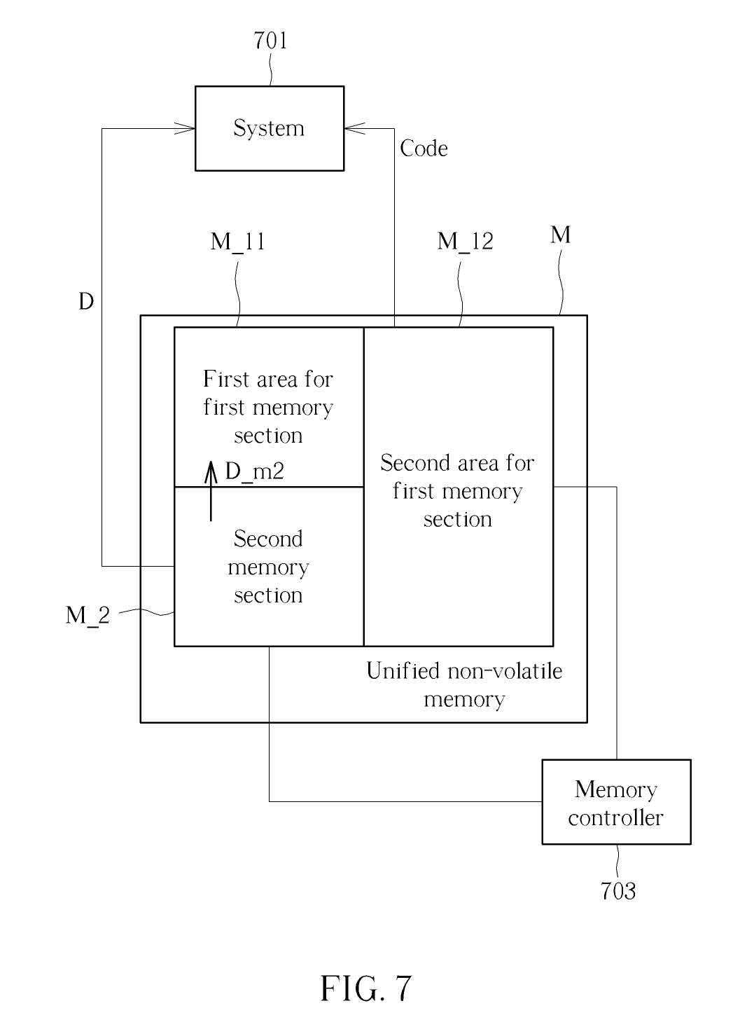

FIG. 7 is a block diagram illustrating an electronic apparatus applying the unified non-volatile memory depicted in FIG. 6. If the system 701, which comprises the control unit 501 depicted in FIG. 5, and the unified non-volatile memory M are both active, the system 701 accesses data D to and from the second memory section M_2, and the system 701 can read code for the control unit Code from the second area for first memory section M_12. Also, if the system 701 is controlled to be turned off, before the non-volatile memory M is completely off, the second memory section M_2 backs up data D_m2 stored thereinto the first area for first memory section M_11. By this way, the first area for first memory section M_11 and the second area for first memory section M_12 are not limited to store code for the control unit, and the data in the second memory section M_2 served as a RAM can be well protected before the system is totally off. The memory controller 703 is applied to control the operations of the first area for first memory section M_11, the second area for first memory section M_12 and the second memory section M_2.

In one embodiment, a power storing unit is further provided in an IC which the memory controller 703 is provided in. The power storing unit can provide power to the memory controller 703 and the non-volatile memory M, such that the data can be backed up to the first area for first memory section M_11 even if the main power is suddenly cut.

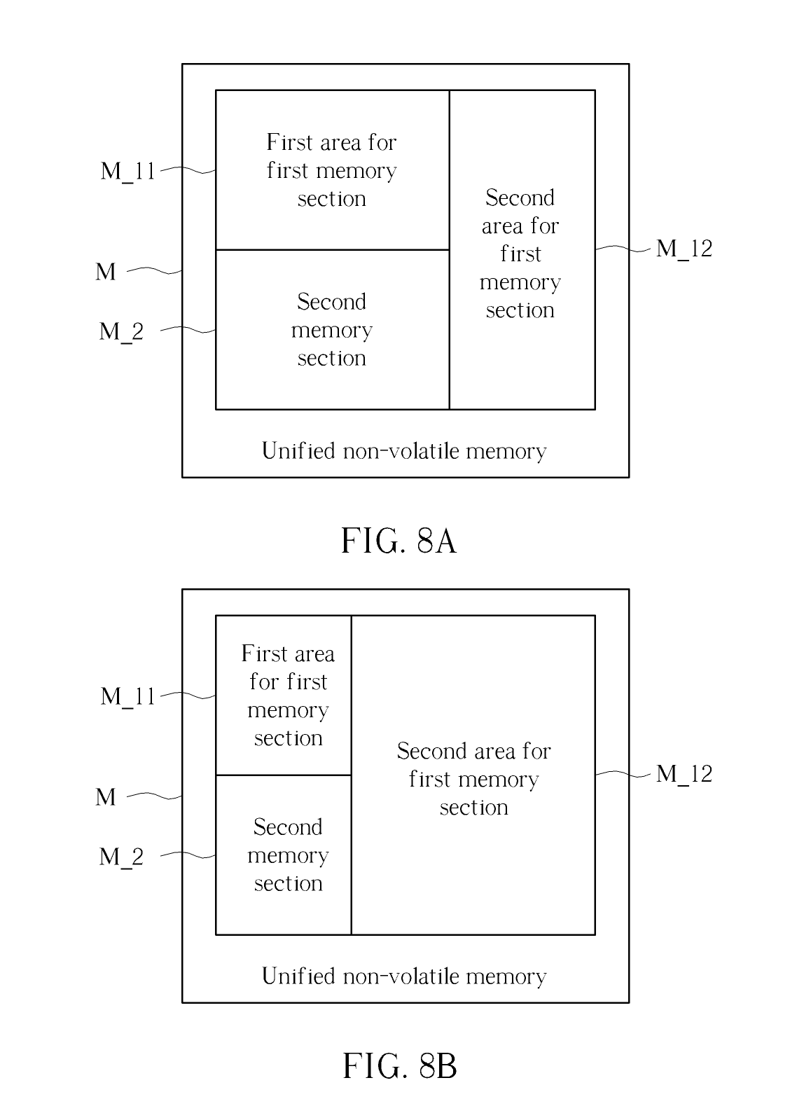

FIG. 8A and FIG. 8B are block diagrams illustrating unified non-volatile memories according to other embodiments of the present invention. In such embodiments, the size(s) or percentage(s) for at least the first area for the first memory section M_11, the second area for first memory section M_12 and the second memory section M_2 is programmable. For more detail, the size(s) or ratio(s) for at least one of the first area for the first memory section M_11, the second area for first memory section M_12 and the second memory section M_2 is decided by a program, which is stored in the second memory section M_2 in one example.

In the examples depicted in FIG. 8A and FIG. 8B, the size of the first area for the first memory section M_11 is the same as which of the second memory section M_2. However, the sizes of the first area for the first memory section M_11 and the second memory section M_2 are different for the examples depicted in FIG. 8A and FIG. 8B. Based on these examples, the density of the unified non-volatile memory M can be programmed to be different.

The architectures in FIG. 2-FIG. 8 can be applied to any kind of electronic apparatus. In one embodiment, the architectures in FIG. 2-FIG. 8 are applied to an electronic apparatus that rarely accesses the second memory section M_2 of the non-volatile memory M. As above-mentioned, access speed of the non-volatile memory is lower than the volatile memory. Nevertheless, the access speed for the second memory section M_2 is sufficient for such electronic apparatus, since the second memory section M_2 is rarely accessed.

In one embodiment, the electronic apparatus architectures in FIG. 2-FIG. 8 are applied to an electronic apparatus applying Internet of Things (IOT). The IoT is the interconnection of uniquely identifiable embedded computing devices within the existing Internet infrastructure. Typically, IoT is expected to offer advanced connectivity of apparatuses, systems, and services that goes beyond machine-to-machine communications (M2M). Things, in the IoT, can refer to a wide variety of apparatuses such as heart monitoring implants, biochip transponders on farm animals, electric clams in coastal waters, automobiles with built-in sensors, or field operation devices that assist fire-fighters in search and rescue.

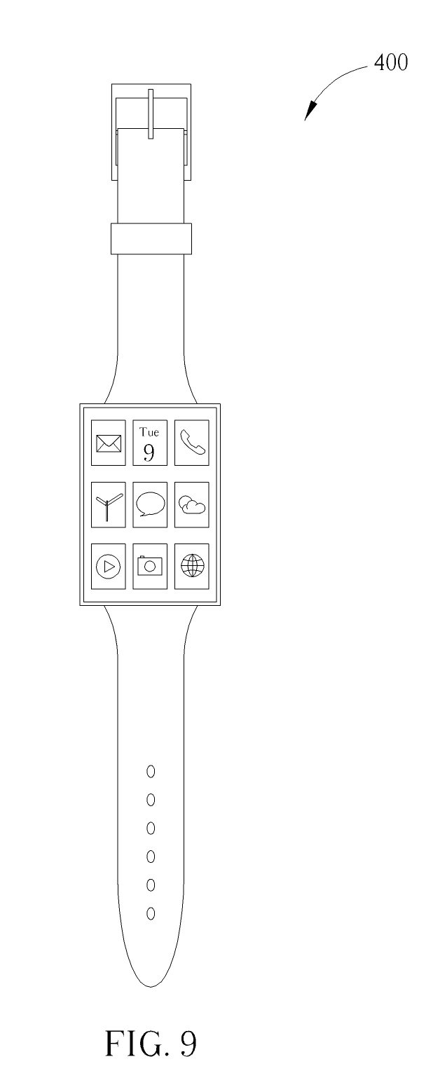

FIG. 9 is a schematic diagram illustrating an electronic apparatus applying IOT according to one embodiment of the present application. As illustrated in FIG. 9, the electronic apparatus 400 is a smart watch, which can provide more functions besides function for a conventional watch. For example, the smart watch 400 can measure the blood pressure and the heart rate of the user and transmit to a server, such that a nursing assistant can remotely monitor health of the user. Alternatively, the user can control an air conditioner in his house via the smart watch, even he is not at home. The memory for such kind of electronic apparatus is accessed more rarely than other electronic devices, such as a smart phone, thus can apply the architecture depicted in FIG. 2-FIG. 8 of the present invention. However, FIG. 9 is only an example and does not mean the architectures depicted in FIG. 2-FIG. 8 can only be applied to such electronic apparatus. For example, the architectures depicted in FIG. 2-FIG. 8 can be applied to a TV applying IOT.

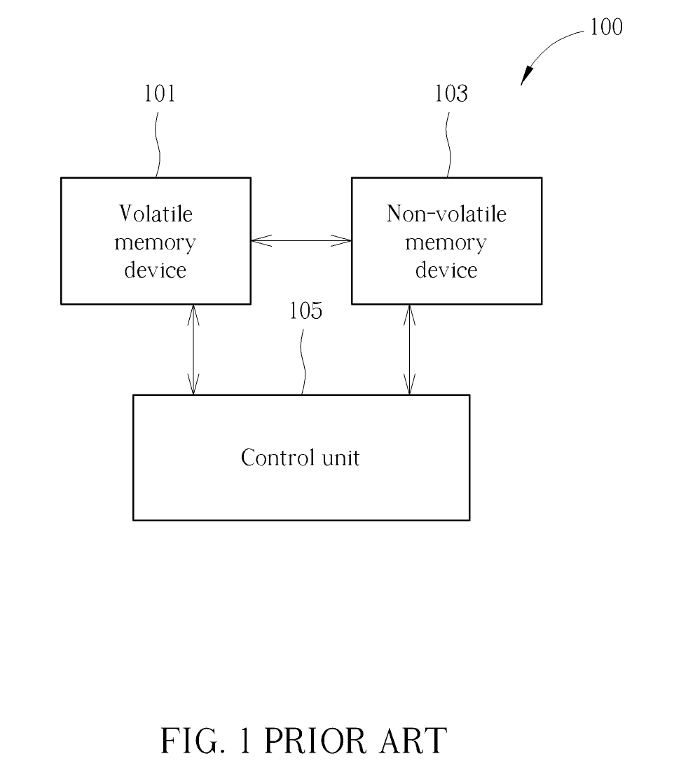

In view of above-mentioned embodiments, a unified non-violate memory is applied to replace two independent memories (a non-violate memory and a volatile memory in FIG. 1), thus the chip size is reduced and simplified. Also, the power consumption is low since no volatile memory is needed. Further, the yield is better and overall manufacture cost is low since only a single manufacture process is needed. Besides, the data retention and the endurance for the memory raises since only non-volatile memories are used.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A unified non-volatile memory, comprising:
a first memory section, served as a read only memory; and
a second memory section, served as a random access memory.

2. The unified non-volatile memory of claim 1, wherein memory endurance of the second memory section is higher than memory endurance of the first memory section.

3. The unified non-volatile memory of claim 1, wherein data retention of the second memory section is lower than data retention of the first memory section.

4. The unified non-volatile memory of claim 1, wherein the unified non-volatile memory is a parameter random access memory.

5. The unified non-volatile memory of claim 1, wherein the unified non-volatile memory is a phase change random access memory.

6. The unified non-volatile memory of claim 1, wherein the unified non-volatile memory is a magnetoresistive random access memory.

7. The unified non-volatile memory of claim 1, wherein the unified non-volatile memory is a ferroelectric random access memory.

8. The unified non-volatile memory of claim 1, wherein the unified non-volatile memory is a conductive-bridging random access memory.

9. The unified non-volatile memory of claim 1, wherein the unified non-volatile memory is a resistive random access memory.

10. The unified non-volatile memory of claim 1, wherein the first memory section further comprises:
a first area for the first memory section; and
a second area for the first memory section.

11. The unified non-volatile memory of claim 10, wherein a percentage of the unified non-volatile memory density for the first memory section, the second area for the first memory section, and the second memory section, are programmable.

12. An electronic apparatus, comprising:
a unified non-volatile memory, comprising:
a first memory section, served as a read only memory; and
a second memory section, served as a random access memory; and
a control unit, for controlling the unified non-volatile memory.

13. The electronic apparatus of claim 12, wherein memory endurance of the second memory section is higher than memory endurance of the first memory section.

14. The electronic apparatus of claim 12, wherein data retention of the second memory section is lower than data retention of the first memory section.

15. The electronic apparatus of claim 12, wherein the first memory section is served as a code memory for the control unit.

16. The electronic apparatus of claim 12, wherein the electronic apparatus is an electronic apparatus applying Internet of Things.

17. The electronic apparatus of claim 12, wherein the unified non-volatile memory is a parameter random access memory.

18. The electronic apparatus of claim 12, wherein the unified non-volatile memory is a phase change random access memory.

19. The electronic apparatus of claim 12, wherein the unified non-volatile memory is a magnetoresistive random access memory.

20. The electronic apparatus of claim 12, wherein the unified non-volatile memory is a ferroelectric random access memory.

21. The electronic apparatus of claim 12, wherein the unified non-volatile memory is a conductive-bridging random access memory.

22. The electronic apparatus of claim 12, wherein the unified non-volatile memory is a resistive random access memory.

23. The electronic apparatus of claim 12, wherein the first memory section further comprises:
a first area for the first memory section; and
a second area for the first memory section.

24. The electronic apparatus of claim 23, wherein a percentage of the unified non-volatile memory density for the first memory section, the second area for the first memory section, and the second memory section, are programmable.

25. The electronic apparatus of claim 23,
wherein the second area for the first memory section is arranged to store code for the control unit;
where the first area for the first memory section does not store code for the control unit and the control unit accesses the code from the second area for the first memory section, while the control unit is active;
wherein data stored in the second memory section is backed up to the first area for the first memory section, while the control unit is off.
